(19) United States
(12) Patent Application Publication
(10) Pub. No.: US 2024/0282788 A1
(43) Pub. Date: Aug. 22, 2024

(54) INTEGRATED CIRCUIT AND IMAGE SENSOR INCLUDING THE SAME

(71) Applicant: Samsung Electronics Co., Ltd., Suwon-si (KR)

(72) Inventors: Yeongseok CHOI, Suwon-si (KR); Hyeokjong LEE, Suwon-si (KR); Kyunghoon KIM, Suwon-si (KR)

(73) Assignee: Samsung Electronics Co., Ltd., Suwon-si (KR)

(21) Appl. No.: 18/487,430

(22) Filed: Oct. 16, 2023

(30) Foreign Application Priority Data
Feb. 21, 2023 (KR) 10-2023-0023153

(51) Int. Cl. H01L 27/146

(52) U.S. Cl. CPC H01L 27/14614; H01L 27/14636

(57) ABSTRACT

Provided are an integrated circuit having a structure advantageous to scaling by eliminating a dummy region of a semiconductor device and an image sensor including the integrated circuit. The integrated circuit may comprise at least one cell, a planar transistor, and a vertical transistor. The at least one cell may comprise a first active region and a second active region adjacent to each other, at least one first active fin on the first active region and extending in a first direction, at least one second active fin on the second active region and extending in the first direction, and an active gate line vertically overlapping the first active region and the second active region and extending in a second direction perpendicular to the first direction.

### CROSS-REFERENCE TO RELATED APPLICATION

This application is based on and claims priority under 35 USC § 119 to Korean Patent Application No. 10-2023-0023153, filed on Feb. 21, 2023, in the Korean Intellectual Property Office, the disclosure of which is incorporated by reference herein in its entirety.

### BACKGROUND

Inventive concepts relate to an integrated circuit (IC) and an image sensor including the same. More specifically, inventive concepts relate to an IC capable of improving the degree of integration by reducing the width of transistors and an image sensor including the same.

Electronic systems utilizing or requiring data storage need semiconductor devices capable of storing high-capacity data, and accordingly, a method of increasing data storage capacity of semiconductor devices has been researched. In addition, with the development of semiconductor process technologies, research into ICs that may efficiently use area has also been conducted.

### SUMMARY

Inventive concepts provide an integrated circuit (IC) having a structure advantageous to scaling by eliminating a dummy region of a semiconductor device, and an image sensor using the IC.

In addition, the problem to be solved by the inventive concepts is not limited to the aforementioned problems, and other problems may be clearly understood by those skilled in the art from the description below.

In order to address the technical problem, the inventive concepts provide the following IC.

In some of the example embodiments, there is provided an integrated circuit including at least one cell and including a planar transistor and a vertical transistor, wherein the at least one cell includes first active regions and second active regions arranged to be adjacent to each other, at least one first active fin extending in a first direction on the first active region, at least one second active fin extending in the first direction on the second active region, and an active gate line extending in a second direction perpendicular to the first direction and vertically overlapping the first active region and the second active region.

In some of the example embodiments, there is provided an integrated circuit including a first cell; and a second cell adjacent to the first cell in a first direction, wherein each of the first cell and the second cell includes a first source/drain region and a second source/drain region extending in a first direction on a substrate and arranged to be adjacent to each other in a second direction, a fin-type active region adjacent to the first source/drain region and the second source/drain region, and a fin-type structure formed in the fin-type active region, wherein the fin-type structure formed in the first cell is the same as the fin-type structure formed in the second cell.

In order to solve the technical problems, the inventive concepts provide the following image sensor.

In some of the example embodiments, , there is provided an image sensor including a semiconductor substrate, a first active region and a second active region located to be adjacent to each other on the semiconductor substrate, first active fins extending in a first direction on the first active region and arranged parallel to each other in a second direction perpendicular to the first direction, second active fins extending in the first direction on the second active region and arranged to be parallel to each other in the second direction, and an active gate line extending in the second direction on the first active fins and the second active fins.

### BRIEF DESCRIPTION OF THE DRAWINGS

Embodiments will be more clearly understood from the following detailed description taken in conjunction with the accompanying drawings:

FIG. 1 is a block diagram illustrating an image sensor according to an embodiment;

FIG. 2 is a cross-sectional view illustrating an integrated circuit (IC) device according to some of the example embodiments;

FIG. 3 is a graph illustrating a yield improvement effect expected from application of an IC according to some example embodiments;

FIGS. 4A and 4B are a circuit diagram and a layout diagram of an inverter circuit according to some example embodiments, respectively;

FIGS. 5A and 5B are a circuit diagram and a layout diagram of an output buffer according to an example embodiment, respectively;

FIGS. 6A and 6B are a circuit diagram and a layout diagram of a level shifter according to an example embodiment, respectively;

FIGS. 7A and 7B are a circuit diagram and a layout diagram of a stacked level shifter according to an example embodiment, respectively; and

FIG. 8 is a schematic diagram illustrating an image sensor according to an embodiment.

### DETAILED DESCRIPTION OF THE EMBODIMENTS

Hereinafter, embodiments are described in detail with reference to the accompanying drawings. The same reference numerals are used for the same components in the drawings, and redundant descriptions thereof are omitted.

Example embodiments may be modified in various forms and various embodiments may be provided, and thus, some embodiments are illustrated in the drawings and described in detail. However, it should be understood that example embodiments are not limited in scope and include all modifications, equivalents, and replacements relating to the technical scope of the inventive concepts. In describing example embodiments, if a detailed description for a related known art is considered to unnecessarily divert from the gist of the inventive concepts, the detailed description has been omitted but be understood by those skilled in the art.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU) , an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Terms used in the embodiments may be interpreted as having meanings commonly understood by those ordinarily skilled in the art unless otherwise defined.

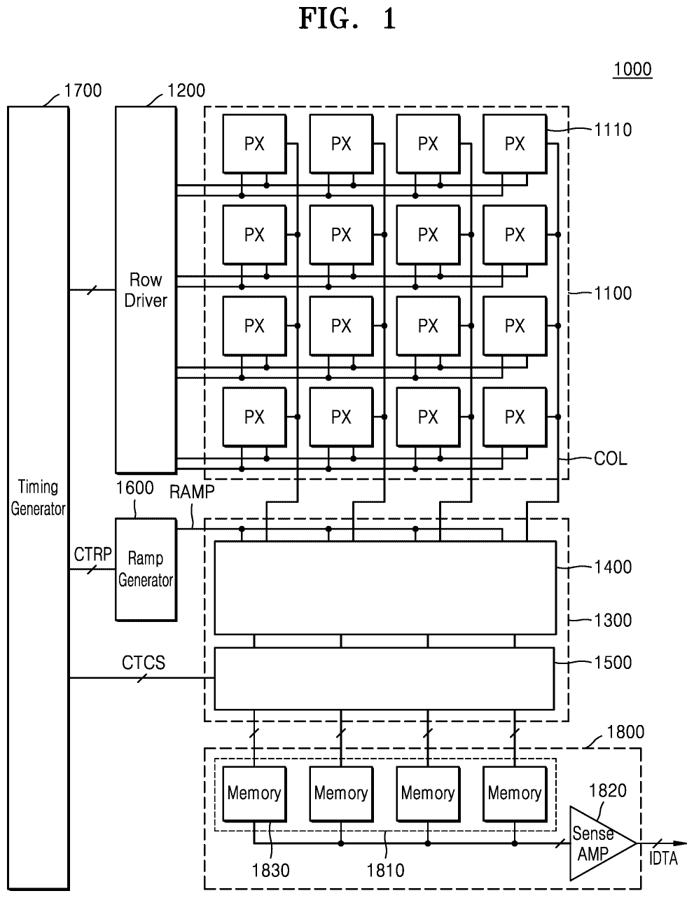

FIG. 1 is a block diagram illustrating an image sensor 1000 according to an embodiment.

The image sensor 1000 may be mounted in an electronic device having an image or light sensing function. For example, the image sensor 1000 may be mounted on electronic devices, such as cameras, smartphones, wearable devices, the Internet of things (IoT), tablet personal computers (PCs), personal digital assistants (PDAs), portable multimedia players (PMPs), GPS systems. In addition, the image sensor 1000 may, for example, be mounted on electronic devices provided as components in vehicles, instruments, manufacturing facilities, doors, and various measuring devices.

The image sensor 1000 may include a pixel array 1100, a row driver 1200, an analog-to-digital converter (ADC) 1300, a ramp generator 1600, a timing generator 1700, and a buffer 1800.

The pixel array 1100 includes a plurality of pixels 1110 arranged in a matrix form and each connected to a plurality of row lines and a plurality of column lines COL. Each of the pixels 1110 may include a photo-sensing device. For example, the photo-sensing device may include a photodiode, a phototransistor, a photo gate, or a pinned photodiode. Each of the pixels 1110 may include at least one photo-sensing device, and in an example embodiment, each of the pixels 1110 may include a plurality of photo-sensing devices.

The pixels 1110 may detect light using the photo-sensing device and convert the detected light into a pixel signal that is an electrical signal. The pixel signal may include a reset signal generated according to a reset operation of each of the pixels 1110 and may include an image signal according to a light-detecting operation of each of the pixels 1110.

Each of the pixels 1110 may detect light of a certain spectral range. For example, the pixels 1110 may include a red pixel converting light in a red spectral range into an electrical signal, a green pixel converting light in a green spectral range into an electrical signal, and a blue pixel converting light in a blue spectral range into an electrical signal. A color filter via by which light in a certain spectral range is transmitted may be disposed above each of the pixels 1110.

The timing generator May 1700 output a control signal or a clock signal to any or each of the row driver 1200, the ADC 1300, and the ramp generator 1600 to control an operation of timing of the row driver 1200, the ADC 1300, and the ramp generator 1600.

The row driver 1200 may drive the pixel array 1100 in units of rows. The row driver 1200 decodes a row control signal (e.g., an address signal) generated by the timing generator 1700 and selects at least one of the row lines constituting the pixel array 1100 in response to the decoded row control signal. For example, the row driver 1200 may generate a row select signal. The pixel array 1100 may output a pixel signal selected by the row select signal provided from the row driver 1200.

The ADC 1300 may convert a pixel signal that is an analog signal input from the pixel array 1100 into a digital signal. The ADC 1300 may include a comparison block 1400 and a counter block 1500.

The comparison block 1400 may compare the pixel signal output from the pixel 1110 connected to the column line COL with a ramp signal RAMP.

The counter block 1500 may include a plurality of counters.

For example, a comparison circuit in the comparison block 1400 may receive a pixel signal from at least one of the column lines COL corresponding thereto, receive the ramp signal RAMP from the ramp generator 1600, compare the pixel signal with the ramp signal RAMP, and output a comparison result signal. The comparison circuit and the counter may be referred to as correlated double sampling (CDS) circuits performing a CDS technique using the comparison result signal and may also be referred to as column parallel CDS circuits.

The pixel signals output from the pixels 1110 may have deviations due to pixel-specific characteristics of each pixel 1110 and/or deviations due to differences in characteristics of logics for outputting the pixel signals from the pixels 1110. The CDS refers to obtaining a reset component (or a reset signal) and an image component (or an image signal) for each of the pixel signals and extracting the difference therebetween as an effective signal component in order to compensate for the deviations between the pixel signals.

The buffer 1800 temporarily stores the digital signal output from the ADC 1300, senses the digital signal, amplifies the sensed digital signal, and outputs the amplified digital signal. The buffer 1800 may include a column memory block 1810 and a sense amplifier 1820, and the column memory block 1810 may include a plurality of memories 1830. The memories 1830 may temporarily store the digital signals respectively output from the counters and output the digital signals to the sense amplifier 1820, and the sense amplifier 1820 may sense the digital signals output from the memories 1830 and amplify the sensed digital signals. The sense amplifier 1820 may output the amplified digital signals as image data IDTA.

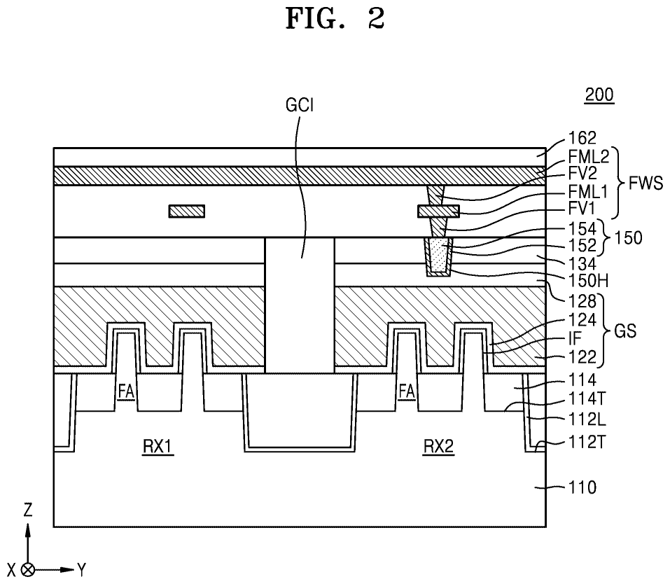

FIG. 2 is a cross-sectional view illustrating an integrated circuit (IC) device 200.

In the following description, various example embodiments of an IC formed on a substrate 110, for example, a semiconductor substrate, are provided. The IC has a layout including various cells. In some example embodiments, the IC may include a circuit constituting the row driver 1200 of FIG. 1. For example, the IC may configure a peripheral circuit that may drive the pixel array 1100 of FIG. 1 in units of rows, decode a row control signal (e.g., an address signal) generated by the timing generator 1700, and select at least one of row lines constituting the pixel array 1100 in response to the decoded row control signal.

For example, the IC may include at least one driving transistor capable of generating a row select signal. For example, the IC may include circuits, such as an inverter, an output buffer, a level shifter, and a stack level shifter, but example embodiments are not limited thereto.

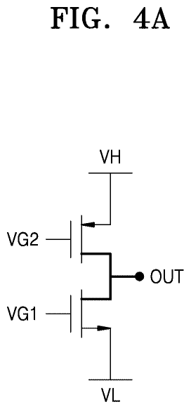

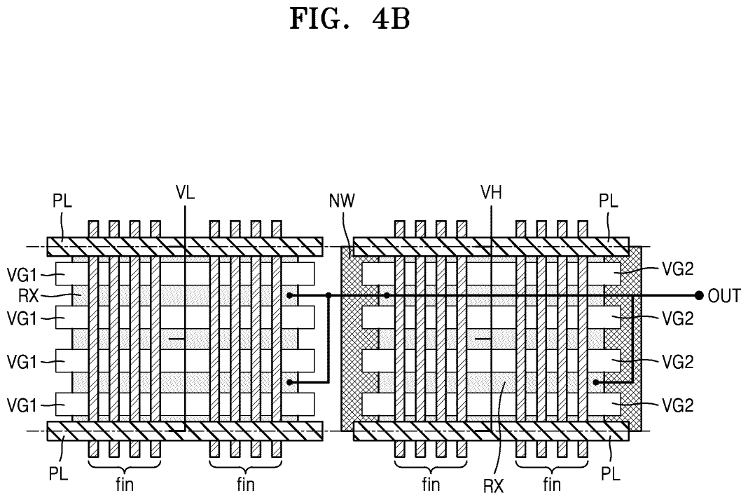

Circuit diagrams for the inverter, output butter, level shifter, stack level shifter, etc., and layout diagrams corresponding to the circuit diagrams are described below with reference to FIGS. 4A, 4B, 5A, 5B, 6A, 6B, 7A, and 7B.

In other example embodiments, the IC may include at least one of circuits of the ADC 1300, the ramp generator 1600, the timing generator 1700, and the buffer 1800 of FIG. 1.

Referring to FIG. 2, the IC device 200 may include a FinFET transistor. Referring to FIGS. 2, 4B, 5B, 6B, and 7B together, an active region RX may include a first active region RX1 and a second active region RX2. For example, a plurality of fin-type active regions FA may protrude from the substrate 110 in the vertical direction Z on the first active region RX1 and the second active region RX2. For example, a transistor disposed on the first active region RX1 may be a PMOS transistor, and a transistor disposed on the second active region RX2 may be an NMOS transistor. In various example embodiments, one fin-type active region FA may be disposed on the first active region RX1, and one fin-type active region FA may be disposed on the second active region RX2.

A shallow device isolation layer 114 may be disposed in a shallow device isolation trench 114T on both sidewalls of the fin-type active region FA, a device isolation trench 112T may be located outside the first active region RX1 and the second active region RX2 and between the first active region RX1 and the second active region RX2, and a device isolation layer 112 may be located in the device isolation trench 112T. The device isolation layer 112 may cover a lower portion of the sidewall of the fin-type active region FA. A gate structure GS may include an interfacial layer IF between a gate insulating layer 124 and the fin-type active region FA, and the interfacial layer IF may include silicon oxide. An insulating liner 112L may be conformally formed on an inner wall of the device isolation trench 112T and be thin or substantially thin.

The IC device 200 may be manufactured through the following process. A sacrificial layer and a channel semiconductor layer may be alternately formed on the substrate 110 to form a preliminary channel stack. For example, the sacrificial layer and the channel semiconductor layer may each include a single crystal layer of a Group IV semiconductor, a

Group IV-IV compound semiconductor, or a Group III-V compound semiconductor, and the sacrificial layer and the channel semiconductor layer may include different materials. In an example, the sacrificial layer may include SiGe, and the channel semiconductor layer may include single crystal silicon.

The sacrificial layer and the channel semiconductor layer may be formed by an epitaxial process. In some example embodiments, the epitaxial process may be a chemical vapor deposition (CVD) process, molecular beam epitaxy, or combinations thereof. In the epitaxial process, a liquid or gaseous precursor may be used as a precursor necessary for forming the sacrificial layer and the channel semiconductor layer.

After a hard mask pattern extending to have a certain length in an X direction on the channel semiconductor layer, the sacrificial layer, the channel semiconductor layer, and the substrate 110 may be etched using the hard mask pattern as an etch mask to form a preliminary channel pattern and the device isolation trench 112T. Thereafter, a portion of the substrate 110 exposed from a bottom portion of the device isolation trench 112T may be further etched to form a buried trench.

One sidewall of the fin-type active region FA may be exposed by the device isolation trench 112T, and the other sidewall of the fin-type active region FA may be exposed by the buried trench. The insulating liner 112L may be formed on an inner wall of the device isolation trench 112T and an inner wall of the buried trench, and a sacrificial buried layer may be formed on the insulating liner 112L.

The sacrificial buried layer located inside the device isolation trench 112T may be subsequently removed by an etch-back process or a recess process, and in an example embodiment, the insulating liner 112L may not be removed but remain. Thereafter, the inside of the device isolation trench 112T may be filled with an insulating material, and an upper portion of the insulating material may then be planarized to form a buried insulating layer filling the device isolation trench 112T. The insulating liner 112L and the buried insulating layer may collectively be referred to as the device isolation layer 112.

A dummy gate structure may be formed on the preliminary channel pattern and the device isolation layer 112. The dummy gate structure may include, for example, a dummy gate insulating layer, a dummy gate line, a dummy gate capping layer, and a spacer film. The spacer film may cover at least a portion of an upper surface of the device isolation layer 112. The dummy gate line may include, for example, polysilicon. The preliminary channel pattern on both sides of the dummy gate structure and a portion of the substrate 110 may be etched to form a recess on both sides of the dummy gate structure. As the recess is formed, the preliminary channel pattern may be divided into a plurality of semiconductor patterns.

Thereafter, source/drain regions may be formed in the recess. The spacer film may be provided to fill the recess in an upper portion of the source/drain region. For example, the source/drain regions may be formed by epitaxially growing a semiconductor material from the semiconductor patterns exposed on the inner wall of the recess, the sacrificial layer, and the surface of the substrate 110. The source/drain region may include at least one of an epitaxially grown Si layer, an epitaxially grown SiC layer, an epitaxially grown SiGe layer, and an epitaxially grown SiP layer.

Thereafter, an inter-gate insulating layer may be formed on a sidewall of the spacer film and the source/drain region. Upper portions of the dummy gate structure and the inter-gate insulating layer may be planarized to remove a dummy gate capping layer of the dummy gate structure and expose an upper surface of the dummy gate line.

The dummy gate line and the dummy gate insulating layer exposed through the inter-gate insulating layer may be removed to form a gate space. Thereafter, the sacrificial layers remaining on the fin-type active region FA may be removed through the gate space to partially expose the semiconductor patterns and an upper surface of the fin-type active region FA.

Thereafter, a gate insulating layer may be formed on surfaces exposed from the gate space, and a gate electrode 122 filling the gate space may be formed on the gate insulating layer. In some example embodiments, the gate electrode 122 may include polysilicon to be doped, metal, conductive metal nitride, conductive metal carbide, conductive metal silicide, or combinations thereof.

An upper insulating layer 134 may be formed on the gate electrode 122 and the inter-gate insulating layer. Thereafter, a mask pattern may be formed on the upper insulating layer, and portions of the inter-gate insulating layer and the upper insulating layer 134 may be removed using the mask pattern as an etching mask to form a power via hole exposing an upper surface of the sacrificial buried layer. A conductive barrier layer and a via metal layer may be sequentially formed on an inner wall of the power via hole.

Portions of the upper insulating layer 134 and the gate capping layer 128 may be removed to form a contact hole 150H, and a conductive barrier layer 154 and a contact plug 152 may be sequentially formed inside the contact hole 150H to form a contact 150.

A front wiring structure FWS including wiring layers FML1 and FML2 and vias FV1 and FV2 and an interlayer insulating film 162 surrounding the front wiring structure FWS may be formed on the upper insulating layer 134.

The front wiring structure FWS may include the wiring layers FML1 and FML2 and the vias FV1 and FV2, and the interlayer insulating film 162 may be disposed on the upper insulating layer 134 to cover the front wiring structure FWS. For example, the interlayer insulating film 162 may include a plurality of material layers, and each of the material layers may cover top and bottom surfaces of the wiring layers FML1 and FML2 and surround sidewalls of the vias FV1 and FV2. In some example embodiments, the interlayer insulating film 162 may include an oxide film, a nitride film, an ultra-low dielectric constant k (ULK) film, or combinations thereof.

The IC device 200 of FIG. 2 may be formed through the above process. However, inventive concepts are not limited thereto.

The IC may include a plurality of fin regions on the substrate 110. The fin regions may have a pillar shape vertically protruding on the substrate 110. The fin regions may have a bar shape extending in the Z direction. The fin regions may include the fin-type active region FA. The fin regions may be spaced apart from each other at equal intervals in the Y direction and may be parallel or substantially parallel to adjacent fin regions in a bar shape extending in the Z direction.

The active region RX (refer to FIGS. 4B, 5B, 6B, and 7B) may be a partial region of the substrate 110 and may be a region doped with N-type and P-type impurities. The active region RX may be formed by doping impurities into the substrate 110 using an ion implantation process or a diffusion process. The active region RX may be formed by etching the substrate 110 to a desired depth using the hard mask pattern as an etch mask on the substrate 110. A semiconductor material layer may then be formed by epitaxial growth in a recessed region defined through semiconductor etching.

In the IC, a fin region may be a channel region having an increased effective channel region area, as compared to a channel region of a planar transistor. When a voltage is applied to the gate electrode 122 to turn on the transistor, carriers may move from the active region RX through a fin structure. For example, the fin region may function as a channel of an NMOS field effect transistor or a PMOS field effect transistor.

A connection metal layer connecting each of the gate electrodes 122 may be provided. The connection metal layer may at least partially overlap the fin structure.

A plurality of metal wirings may be formed to correspond to the vias FV1 and FV2.

An input wiring, which is part of the wiring layers FML1 and FML2, may be formed to extend in the Y direction on the vias FV1 and FV2 to be connected to the contact 150 through the vias FV1 and FV2. An output wiring, which is part of the wiring layers FML1 and FML2, may be formed to extend in the Y direction on the vias FV1 and FV2 to be connected to the contact 150 through the vias FV1 and FV2. However, unlike the wiring layers FML1 and FML2 shown in FIG. 2, the wiring layers FML1 and FML2 may include three or more wiring layers.

The contact 150 may be connected to the input wiring through the vias FV1 and FV2. The input wiring extends in the Y direction and is spaced apart from a power wiring in the Y direction.

An interlayer insulating layer may be formed between a plurality of source/drain contacts and between the source/drain regions. The interlayer insulating layer may include a low-k dielectric material.

The output wiring may be electrically connected to the contact 150 through the vias FV1 and FV2. Each of the vias FV1 and FV2 and the output wiring may be located together with the interlayer insulating layer on a plane. An intermediate connection wiring may be located to extend on a connection via located on the input wiring and another connection via located on the output wiring to connect the connection via located on the input wiring to the other connection via located on the output wiring.

According to various example embodiments, a cell may be implemented as a multi-height cell including at least three power wirings and at least two active regions RX1 and RX2.

Because the fin structures are regularly arranged without a dummy fin region and a cell boundary may be demarcated, layout errors appearing at the cell boundary may be reduced and the IC may be more freely designed.

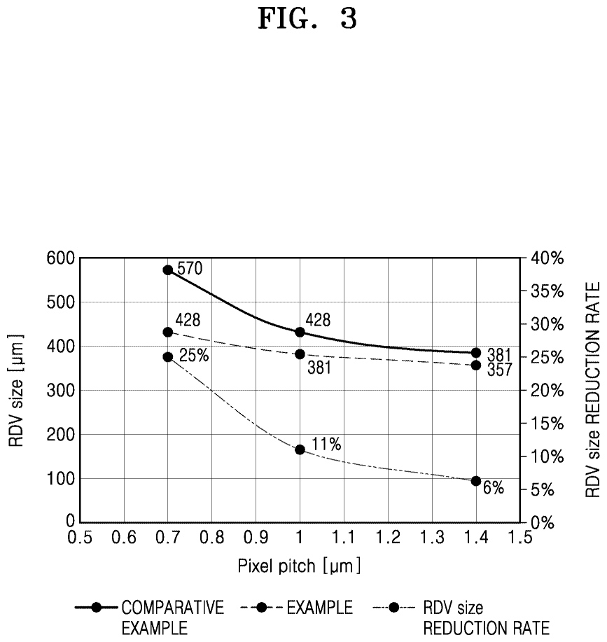

FIG. 3 is a graph illustrating a yield improvement effect expected from application of an IC according to some example embodiments.

Referring to FIG. 3, it can be seen that, when the IC according to some example embodiments is applied to an actual product, the area of an address recorder circuit decreases by 25%, the area of the entire chip decreases by 2.07%, and the production of chips per substrate increases by 2.11%, as compared to the Comparative Example.

The row driver (RDV) size in the graph of FIG. 3 refers to the size of an RDV. In designing a CMOS image sensor in a FinFET process, the arrangement of fins in the vertical direction to achieve the characteristics of a column ADC may be disadvantageous to the layout of the row driver. As pixels have become miniaturized, an array spacing has gradually decreased.

Here, the proportion occupied by a dummy region may relatively increase to degrade area efficiency, but upon application of some example embodiments, adjacent regions between arrays may be removed and a common drain voltage VDD or ground GND line may be connected to a node shared with an adjacent array, thereby improving the area efficiency of the row driver RDV.

FIGS. 4A and 4B are a circuit diagram and a layout diagram of an inverter circuit according to an example embodiment, respectively. In FIG. 4B, PL denotes a power line, RX denotes an active region (RX layer), NW denotes an N-well, and fin denotes a fin structure.

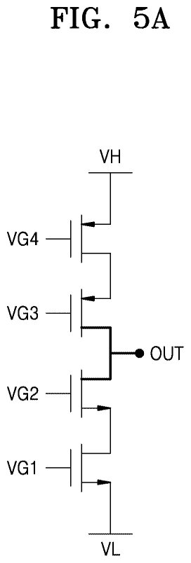

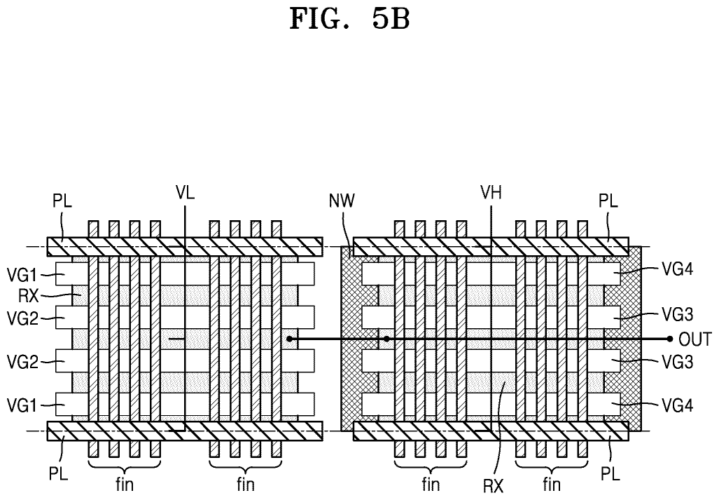

The active region RX may include the first active region RX1 and the second active region RX2. This means the same in the layout diagrams of FIGS. 5B, 6B, and 7B to be described below. In addition, VG1 and VG2 shown in FIG. 4B refer to gate lines, respectively.

Referring to FIG. 4B, it can be seen that, by eliminating a dummy region generally provided between a plurality of gate lines and the power line PL to improve process reliability, the gate lines, not a dummy line, are located even in a region adjacent to the power line PL, like a region not adjacent to the power line PL.

FIGS. 5A and 5B are a circuit diagram and a layout diagram of an output buffer according to an some example embodiments, respectively. The output buffer of FIG. 5A may cover a pixel array that is an output load.

Referring to FIG. 5B, which is a layout diagram of the output buffer of FIG. 5A, gate lines located in a region in which new wells NWs are not formed correspond to VG1, VG2, VG2, and VG1 of FIG. 5A, respectively, from the top, and gate lines located in a region in which the new wells NWs are formed correspond to VG4, VG3, VG3, and VG4 of FIG. 5A, respectively, from the top. VG1, VG2, VG3, and VG4 indicated in FIG. 5B may refer to gate lines, respectively. Also, in the layout diagram of the output buffer, it can be seen that, by eliminating a dummy region between the gate lines and the power line PL to improve the degree of integration of the circuit, the gate lines, not a dummy line, are arranged in the region adjacent to the power line PL in addition to being arranged in the region not adjacent to the power line PL.

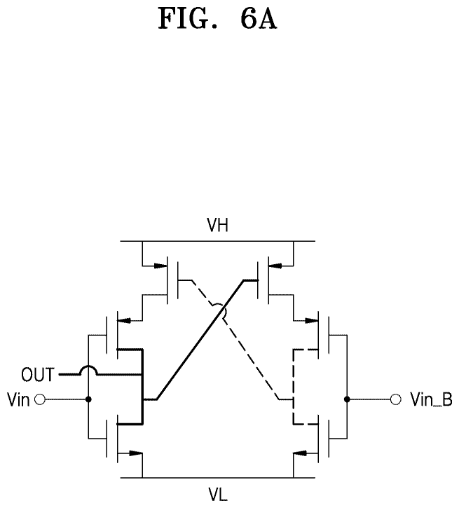

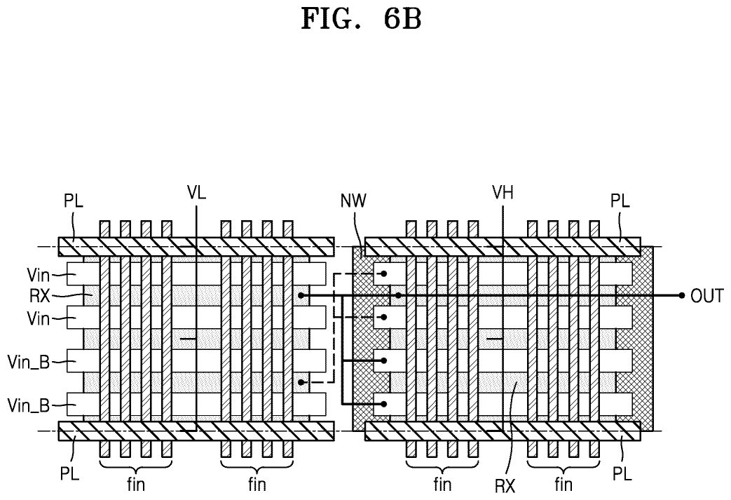

FIGS. 6A and 6B are a circuit diagram and a layout diagram of a level shifter according to some example embodiments, respectively. The level shifter of FIG. 6A is a circuit that shifts an output signal into a voltage region for a pixel gate. The level shifter may serve as an interface between circuits using different power supply voltages. For example, a word line driver of a semiconductor memory device uses a voltage VPP that is higher than an externally supplied voltage VDD, and a signal for driving the word line driver swings between the VDD and a source voltage VSS, while the word line driver needs a swing between the VPP and the VSS. Therefore, directly connecting two circuits without level conversion may cause a current leakage flowing in a circuit using the VPP as a power supply voltage, and thus, the two circuits may be connected using a level shifter.

Referring to FIG. 6B, which is a layout diagram of FIG. 6A, the gate lines arranged in the region in which an N-well NW is not formed correspond to Vin, Vin, Vin_B, and Vin_B of FIG. 6A, respectively, from the top. In the region in which the N-well NW is formed, four lines, Vin and Vin_B, which are spaced apart from each other in the Y-direction and extend in the X-direction, respectively, between power lines PL respectively located at the top and the bottom refer to gate lines. In the layout diagram of the level shifter, it can be seen that, by eliminating a dummy region between the gate lines and the power line PL to improve the degree of integration of the circuit, the gate lines, not a dummy line, are arranged even in the region adjacent to the power line PL, like the region not adjacent to the power line PL. As a result, the degree of integration of the circuit may be improved.

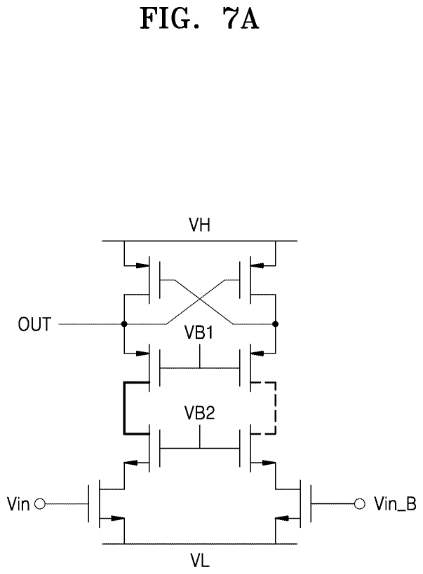

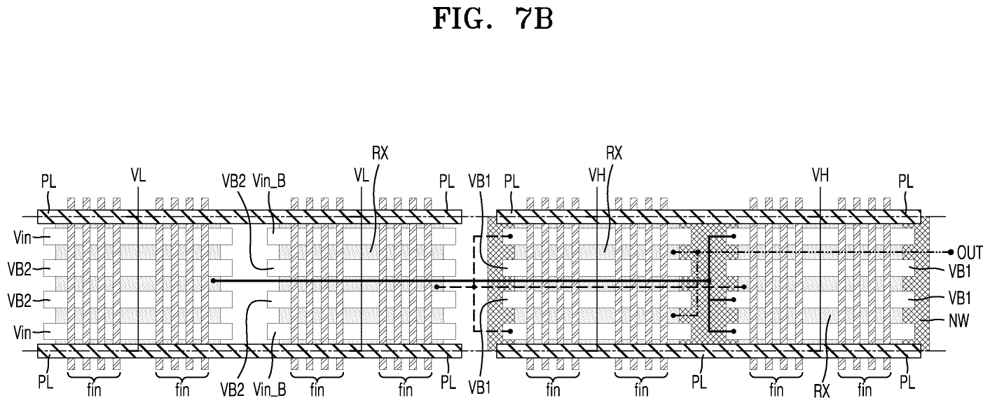

FIGS. 7A and 7B are a circuit diagram and a layout diagram of a stacked level shifter according to an example embodiment, respectively. Referring to FIG. 7B, which is a layout diagram of FIG. 7A, gate lines arranged on the left of a region in which an N-well NW is not formed correspond to Vin, VB2, VB2, and Vin of FIG. 7A, respectively, from the top, and gate lines arranged on the right correspond to Vin_B, VB2, VB2, and Vin_B of FIG. 7A, respectively, from the top. The middle two gate lines of the four gate lines arranged on the left of the region in which the NW is formed and the middle two gate lines, of the four gate lines arranged on the right all correspond to VB1 of FIG. 7A. Also, in the layout diagram of the stack level shifter, it can be seen that, by eliminating a dummy region between the gate lines and the power line PL in both the region in which an N-well NW is formed and the region in which the N-well NW is not formed, the gate lines, not a dummy line, are arranged even in the region adjacent to the power line PL, like the region not adjacent to the power line PL. Through the above process, the degree of integration of the stack level shifter circuit may be improved.

Some example embodiments may include an image sensor including an IC having an improved degree of integration.

The image sensor may include a semiconductor substrate, a plurality of active regions adjacent to each other on the semiconductor substrate, a plurality of active fins extending in the first direction on each active region and arranged in parallel in the second direction perpendicular to the first direction, and an active gate line extending in the second direction on the active fins.

The active fins may be spaced apart from each other at regular intervals. The active gate line may intersect at least one of the active fins on the active region. Each of the active regions may independently correspond to an NMOS transistor formation region or a PMOS transistor formation region. The active fins may correspond to the fins of FIGS. 4B, 5B, 6B, and 7B. The image sensor may be a CMOS image sensor.

Because each active region included in the image sensor does not include a dummy gate line, the area efficiency of transistors included in the image sensor may be improved. The active regions may correspond to the active region RX of FIGS. 4B, 5B, 6B, and 7B. In some example embodiments, a dummy region of adjacent portions between arrays may be removed and a common drain voltage or ground may be connected to a node shared with an adjacent array.

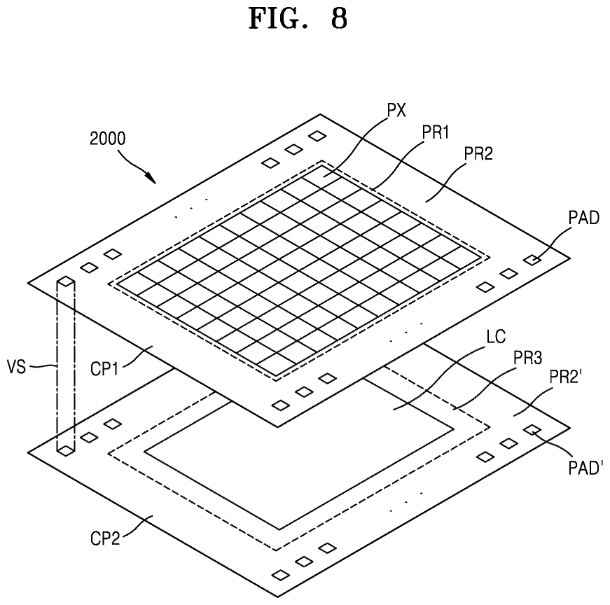

FIG. 8 is a schematic diagram illustrating an image sensor 2000 according to a some example embodiments.

Referring to FIG. 8, the image sensor 2000 may be a stacked image sensor including a first chip CP1 and a second chip CP2 stacked in the vertical direction. The image sensor 2000 may be an implementation of the image sensor 1000 described above with reference to FIG. 1.

The first chip CP1 may include a pixel region PR1 and a pad region PR2, and the second chip CP2 may include a peripheral circuit region PR3 and a lower pad region PR2′. A pixel array in which a plurality of pixels PX are arranged may be formed in the pixel region PR1.

The peripheral circuit region PR3 of the second chip CP2 may include the logic circuit block LC and may include a plurality of transistors. For example, the logic circuit block LC may include at least one of the row driver 1200, the ADC 1300, the ramp generator 1600, the timing generator 1700, and the buffer 1800 described above with reference to FIG. 1.

The lower pad region PR2′ of the second chip CP2 may include a lower conductive pad PAD′. The lower conductive pad PAD′ may be included as a plurality, and each of the lower conductive pads may correspond to upper conductive pads PAD, respectively. The lower conductive pad PAD′ may be electrically connected to the upper conductive pad PAD of the first chip CP1 through a via structure VS.

The image sensor 2000 may further include a memory. The memory may be formed in the second chip CP2. However, inventive concepts are not limited thereto, and unlike the configuration shown in FIG. 9, the memory may be formed in a third chip separated from the first chip CP1 and the second chip CP2 and may have a structure configured such that the first chip CP1, the second chip CP2, and the third chip are stacked.

While the inventive concepts have been particularly shown and described with reference to some example embodiments thereof, it will be understood that various changes in form and details may be made therein without departing from the spirit and scope of the following claims.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

What is claimed is:

1. An integrated circuit, comprising:
at least one cell;
a planar transistor; and
a vertical transistor, wherein
the at least one cell comprises
a first active region and a second active region adjacent to each other;
at least one first active fin on the first active region and extending in a first direction;
at least one second active fin on the second active region and extending in the first direction; and
an active gate line vertically overlapping the first active region and the second active region and extending in a second direction perpendicular to the first direction.

2. The integrated circuit of claim 1, wherein the at least one cell is defined by a cell boundary having a width in the first direction and a height in the second direction.

3. The integrated circuit of claim 1, wherein
the active gate line intersects with the at least one first active fin on the first active region, and
each of the first active region and the second active region is independently an NMOS transistor region or a PMOS transistor region.

4. The integrated circuit of claim 1, wherein mutually adjacent cell arrays share a node configured for application of a common voltage thereto.

5. The integrated circuit of claim 4, wherein the common voltage is configured to be connected to at least one of a drain voltage VDD or ground.

6. The integrated circuit of claim 1, further comprising:
a first contact on a portion of the active gate line; and
second contacts on the at least one first active fin and on both sides of the active gate line.

7. The integrated circuit of claim 1, wherein the at least one first active fin and the at least one second active fin are spaced apart from each other at regular intervals.

8. The integrated circuit of claim 1, further comprising:
a spacer film between the at least one first active fin and the at least one second active fin.

9. The integrated circuit of claim 1, wherein neither the first active region nor the second active region include a dummy gate line.

10. The integrated circuit of claim 1, further comprising:
a connection metal layer between the at least one first active fin and the at least one second active fin;
an input wiring on the connection metal layer and connected to at least one of gate electrodes through a gate via to receive an input signal; and
an output wiring covering at least a portion of one of the at least one first active region or the at least one second active region, connecting the at least one first active region to the at least one second active region through source/drain vias, and extending in the second direction.

11. The integrated circuit of claim 10, further comprising:
a first connection via on the output wiring of a first cell of the at least one cell;
a second connection via disposed on the input wiring of a second cell of the at least one cell; and
an intermediate connection wiring on the first connection via and the second connection via, connecting the first connection via to the second connection via, and extending in the first direction.

12. An image sensor, comprising:
a semiconductor substrate;
a first active region and a second active region located adjacent to each other on the semiconductor substrate;
first active fins on the first active region, extending in a first direction, and parallel to each other in a second direction perpendicular to the first direction;
second active fins on the second active region, extending in the first direction, and parallel to each other in the second direction; and
an active gate line on the first active fins and the second active fins and extending in the second direction.

13. The image sensor of claim 12, wherein neither the first active region nor the second active region include a dummy gate line.

14. The image sensor of claim 12, wherein a plurality of cells adjacent to each other share a node configured for application of a common voltage thereto.

15. The image sensor of claim 12, wherein the active gate line intersects with at least one of the first active fins on the first active region, and each of the first active region and the second active region is independently an NMOS transistor region or a PMOS transistor region.

16. The image sensor of claim 12, wherein the first active fins and the second active fins are spaced apart from each other at regular intervals.

17. An integrated circuit, comprising:
a first cell; and
a second cell adjacent to the first cell in a first direction, wherein
each of the first cell and the second cell comprises
a first source/drain region and a second source/drain region extending in a first direction on a substrate and adjacent to each other in a second direction;
a fin-type active region adjacent to the first source/drain region and the second source/drain region; and
a fin-type structure in the fin-type active region, and
the fin-type structure in the first cell is the same as the fin-type structure in the second cell.

18. The integrated circuit of claim 17, wherein each of the first cell and the second cell further comprises:
first and second source/drain contacts on the first source/drain region and the second source/drain region, connected to at least one of the first source/drain region and the second source/drain region, respectively, and extending in an X direction.

19. The integrated circuit of claim 17, wherein the first cell and the second cell share a node and neither the first cell nor the second cell include a dummy gate line.

20. The integrated circuit of claim 17, further comprising a spacer film between the fin-type structure in the first cell and the fin-type structure in the second cell.
